(19) United States
(12) Patent Application Publication
(10) Pub. No.: US 2012/0048349 A1
(43) Pub. Date: Mar. 1, 2012

(54) FLEXIBLE SOLAR MODULES AND MANUFACTURING THE SAME

(75) Inventors: Burak Metin, San Jose, CA (US); Eric Lee, San Jose, CA (US); Mustafa Pinarbasi, Morgan Hill, CA (US); Deepak Nayak, Fremont, CA (US)

(73) Assignee: SoloPower, Inc., San Jose, CA (US)

(21) Appl. No.: 13/219,484

(22) Filed: Aug. 26, 2011

Related U.S. Application Data
(63) Continuation-in-part of application No. 12/972,367, filed on Dec. 17, 2010.
Application No. 12/972,367 is a continuation-in-part of application No. 12/685,540, filed on Jan. 11, 2010.
(60) Provisional application No. 61/143,744, filed on Jan. 9, 2009.

(51) Int. Cl. H01L 31/048

(52) U.S. Cl. 136/251

(57) ABSTRACT

A flexible solar cell assembly having solar cells that are positioned within a sealed module chamber. A sealed wiring chamber is positioned on an end of the sealed module chamber and is interposed between the sealed module chamber and a junction box. Wiring interconnecting the junction box to the solar cells in the sealed module chamber is routed through the sealed wiring chamber to inhibit water entry into the sealed module chamber via the wiring.

### CROSS-REFERENCE TO RELATED APPLICATIONS

This application is a continuation in part of U.S. application Ser. No. 12/972,367, filed Dec. 17, 2010 which is a continuation-in-part of U.S. application Ser. No. 12/685,540 filed Jan. 11, 2010, entitled RELIABLE THIN FILM PHOTOVOLTAIC MODULE STRUCTURES, which claimed the benefit of U.S. Provisional Application No. 61/143,744 filed Jan. 9, 2009 which are hereby incorporated in their entirety by reference herein.

### BACKGROUND

1. Field of the Inventions

The aspects and advantages of the present inventions generally relate to apparatus and methods of photovoltaic or solar module design and fabrication and, more particularly, to roll-to-roll or continuous packaging techniques for flexible modules employing thin film solar cells.

2. Description of the Related Art

Solar cells are photovoltaic (PV) devices that convert sunlight directly into electrical energy. Solar cells can be based on crystalline silicon or thin films of various semiconductor materials, that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells including copper indium gallium diselenide (CIGS) based solar cells have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂, is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

In standard CIGS as well as Si and amorphous Si module technologies, the solar cells can be manufactured on flexible conductive substrates such as stainless steel foil substrates. Due to its flexibility, a stainless steel substrate allows low cost roll-to-roll solar cell manufacturing techniques. In such solar cells built on conductive substrates, the transparent layer and the conductive substrate form the opposite poles of the solar cells. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells contained in the packaging against mechanical damage. Each module typically includes multiple solar cells which are electrically connected to one another using the above mentioned stringing or shingling interconnection methods.

In standard silicon, CIGS and amorphous silicon cells that are fabricated on conductive substrates such as aluminum or stainless steel foils, the solar cells are not deposited or formed on the protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. For the Group IBIIIAVIA compound solar cell shown in FIG. 1, if the substrate 11 is a conductive material such as a metallic foil, the substrate, which forms the bottom contact of the cell, becomes the (+) terminal of the solar cell. The metallic grid (not shown) deposited on the transparent layer 15 is the top contact of the device and becomes the (−) terminal of the cell. When interconnected by a shingling process, individual solar cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. Stringing is typically done by placing the cells side by side with a small gap between them and using conductive wires or ribbons that connect the (+) terminal of one cell to the (−) terminal of an adjacent cell. Solar cell strings obtained by stringing or shingling individual solar cells are interconnected to form circuits. Circuits may then be packaged in protective packages to form modules. Each module typically includes a plurality of strings of solar cells which are electrically connected to one another.

Generally, the most common packaging technology involves lamination of circuits in transparent encapsulants. In a lamination process, in general, the electrically interconnected solar cells are covered with a transparent and flexible encapsulant layer. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, they must be further sealed from the environment by a protective shell, which provides resistance to moisture transmission into the module package.

The nature of the protective shell determines the amount of water that can enter the package. The protective shell includes a front protective sheet through which light enters the module and a back protective sheet and optionally an edge sealant that is at the periphery of the module structure. The top protective sheet is typically transparent glass which is water impermeable. The back protective sheet may be a sheet of glass or a polymeric sheet of TEDLAR® (a product of DuPont) and polyeyhylene teraphthalate (PET). The back protective polymeric sheet may or may not have a moisture barrier layer in its structure such as a metallic film like an aluminum film. The edge sealant is a moisture barrier material that may be in the form of a viscous fluid which may be dispensed from a nozzle to the peripheral edge of the module structure or it may be in the form of a tape which may be applied to the peripheral edge of the module structure.

A junction box is typically attached on the exposed surface of the back protective sheet, right below the interconnected solar cells, using moisture barrier adhesives. Terminals of the interconnected solar cells are typically connected to the junction box through holes formed in the back protective sheet. In this way, the size of the module can be reduced as the frame holding the cells can be positioned very close to the solar cells. The holes in the back protective sheet must be very carefully sealed against moisture leakages using, for example, potting materials such as silicone, epoxy, butyl, and urethane containing materials. If the seal in the holes fails, such holes allow moisture to enter the module and can cause device failures.

Thin film solar cells are more moisture sensitive than the crystalline Si devices; therefore, materials with moisture barrier characteristics need to be used in the module structure and any potential moisture sources such as holes in the back and front protective sheets are problematic. For a flexible module to last 25 years, all the packaging components are also required to preserve mechanical, thermal, and chemical stability in the outdoors. The front protective sheet for thin film devices can be either glass or a flexible sheet depending on the product design requirements. A flexible front sheet can be composed of a combination of one or more weatherable films, such as fluoropolymers, for example, ETFE (ethylene-tetrafluoroethylene) or FEP (fluoro ethylene propylene) or polyvinylidene fluoride (PVDF) and a transparent inorganic moisture barrier layer such as Al₂O₃ or SiO₂. In one product, a weatherable film (ETFE, FEP or PVDF) can be laminated onto one or more inorganic moisture barrier layers to form a front protective sheet. However, during the lamination, stresses resulting from UV exposure, temperature cycle and humidity can deteriorate the front protective sheet which can result in severe inorganic moisture barrier-layer delaminations from the weatherable films. One can alleviate these problems by first incorporating the inorganic barrier layers onto a carrier film like poly(ethylene teraphthalate) PET and poly(ethylene naphthalate) PEN and then applying the weatherable film onto the carrier film instead of the barrier layer. Such carrier polymers are thermally and mechanically more stable. Although PET and PEN films are not as weatherable as the ETFE and FEP films, any temperature cycling on the solar panel would not impose as much stress as it would on a fluoropolymer like ETFE, FEP.

Weatherable films can also be incorporated into the moisture barrier layer-carrier film combinations using various adhesives. The adhesion of the weatherable film to the adhesives and adhesives to the moisture barrier layer-carrier film becomes very critical. As mentioned above, fluoropolymers are known to be very difficult to adhere to. For a target 25 years of life time, one would need a very strong adhesion among the layers of weatherable film-adhesive-moisture barrier layer-carrier film. If the adhesion is weak on one of the interfaces, the reliability of the whole product will be in question as any delamination can continue to propagate.

The weakness of the adhesion among the layers of the front protective sheet can also be problematic for junction box adhesion to the front protective sheet. Junction boxes conventionally have been attached to back sides of the modules and on the back protective sheet, which is made of glass or TEDLAR, due to the restrictions on the type of rigid solar panel installations. For a flexible module, there are implementations where the junction boxes should be attached on the front, especially when the modules are required to be incorporated onto the rooftop membranes. However, once the junction box is placed on the front surface of a flexible module, there are adhesion issues with the ETFE and FEP fluoropolymers as explained above, and extra processes steps (performed at additional cost) may be needed to improve adhesion between the top of the weatherable film and the junction box sealant or tape. Further, the weaker adhering front sheet layers are more likely to delaminate where the junction box is placed due to stress mismatches between the solar panel and the junction box. The delamination of one of the front sheet layers around the junction box area can create safety hazards as water can penetrate through the delaminated areas and touch live wires inside the junction box.

As the brief discussion above demonstrates, there is a need to develop new module structures, especially for thin film solar cells, to eliminate aforementioned problems while minimizing moisture permeability.

### SUMMARY

The aforementioned needs are satisfied by at least one embodiment of the present invention which comprise a flexible solar power apparatus that includes a first flexible bottom sheet and a second flexible top sheet, a plurality of side sealing regions interposed between the first flexible bottom sheet and the second flexible top sheet so as to define at least one sealed module chamber having an interior space and exterior surfaces, a solar cell circuit with interconnected solar cells having terminal wires positioned within the sealed module chamber; and a junction box formed on a first exterior surface of the at least one sealed module chamber, wherein terminal wires of the solar cell circuit are extended from the at least one sealed module to the junction box through a first one of the plurality of side sealing regions so as to be surrounded by the material of the side sealing region from the interior space of the at least one sealed module chamber to a positioned adjacent the first exterior surface of the at least one sealed module chamber.

The aforementioned needs are also satisfied by another embodiment of the present invention which comprises a flexible solar panel that includes a bottom protective sheet of a first material, a front protective sheet formed of a second material spaced from the bottom protective sheet, so as to define a space therebetween an edge moisture sealant wall formed between the bottom protective sheet and the front protective sheet along the perimeters of the bottom and the front protective sheet, thereby sealing the perimeters of the bottom protective sheet and the front protective sheet against moisture so as to define a sealed module chamber, a solar cell circuit having terminal wires including a plurality of interconnected solar cells is disposed in the sealed module chamber, a moisture protection layer that is positioned in the sealed module chamber so as to inhibit moisture intrusion toward the solar cells from the direction of the front protective sheet; and a junction box mounted on the flexible solar panel that is connected to the terminal wires of the solar cell circuit.

These and other objects and advantages of the present invention will become more apparent from the following description take in conjunction with the accompanying drawings.

### BRIEF DESCRIPTION OF THE DRAWINGS

FIG. 1 is a schematic view a thin film solar cell;

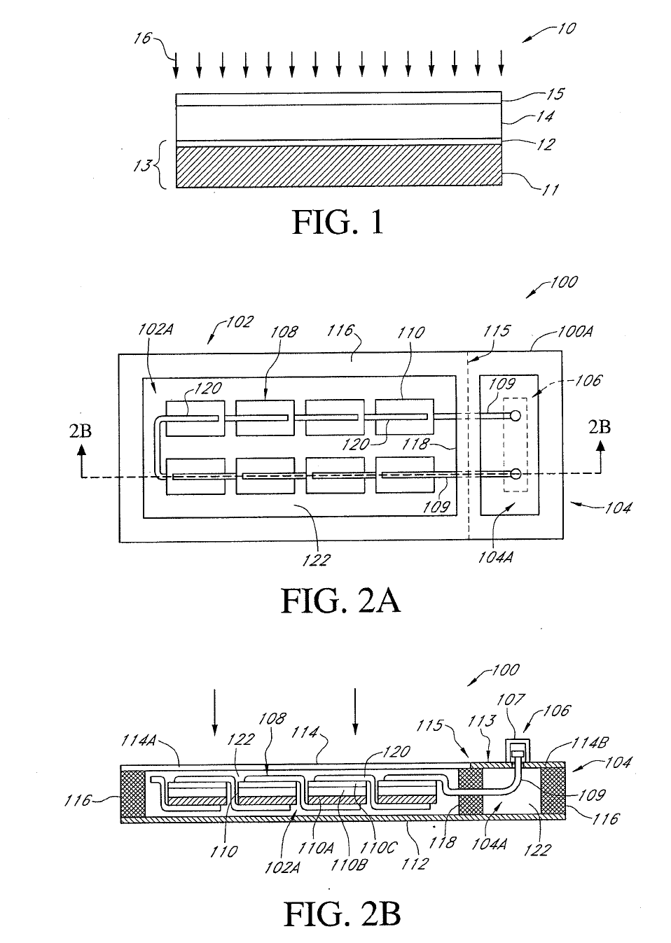

FIG. 2A is a schematic cross sectional view of a flexible thin film solar panel;

FIG. 2B is a schematic cross sectional view of the flexible solar panel shown in FIG. 2A;

FIGS. 3-4 are schematic views of various embodiments of the auxiliary unit and the junction box of the flexible panel;

FIGS. 5-6 are schematic views of various alternative embodiments of a flexible solar panel;

FIGS. 7A-7C are schematic views of another embodiment of a solar cell assembly having moisture barrier layers;

FIGS. 8A and 8B are schematic views of another embodiment of a solar cell assembly having a junction box on the bottom side of the assembly; and

FIGS. 9A to 9D are schematic views of additional embodiments of a solar cell assembly.

### DETAILED DESCRIPTION OF THE PREFERRED EMBODIMENTS

The preferred embodiments described herein provide methods of manufacturing a flexible photovoltaic power apparatus or solar panel including one or more flexible solar modules employing interconnected thin film solar cells, preferably Group IBIIIAVIA compound solar cells. The photovoltaic power apparatus or solar panel preferably includes a sealed module chamber with a first top protective sheet and a sealed wire chamber with a second top protective sheet. A connection box or a junction box through which the apparatus is connected to a power circuitry may be attached to the sealed wire chamber so that the terminal wires of the interconnected solar cells are extended from the sealed module chamber to the junction box through the sealed wire chamber.

The first top protective sheet is a transparent light receiving top protective sheet. The second top protective sheet is different from the first top protective sheet of the sealed module chamber. The second top protective sheet may be of a high moisture resistive material and may not be transparent to visible light. The first and second top protective sheets form the front side of the solar panel, which may be manufactured as a single piece with the first and second top protective sheet portions or by attaching the second protective sheet to the first top protective sheet using various bonding and sealing methods.

The chambers may be formed side by side and separated from one another by a common sealant wall or abutted individual sealant walls belonging to the chambers. Both chambers may be formed on the same back protective sheet or different back protective sheets. In either case, the first and second top protective sheets form the front side of the solar panel. In the preferred embodiment, the second top protective sheet covering the wire chamber includes the same material as the back protective sheet and the junction box is placed on the wire chamber by attaching it to the second top protective sheet As described above in the background, in rigid and flexible module structures employing thin film solar cells, it is important to minimize moisture permeability of the module structure while assuring that the structure passes the electrical safety tests necessary for safe operation in the field. In one embodiment, the current invention is related to a method for a flexible module design where the junction box is on the front side of a solar module and is attached to a back sheet material that is not as hard to adhere as the weatherable ETFE, FEP films. In another embodiment, the current invention also provides unique dielectric materials and lay-up structure to inhibit any electrical wet leakage failures. Both advantages bring improved reliability and safety for the flexible solar panel to enhance its ability to last at least 25 years.

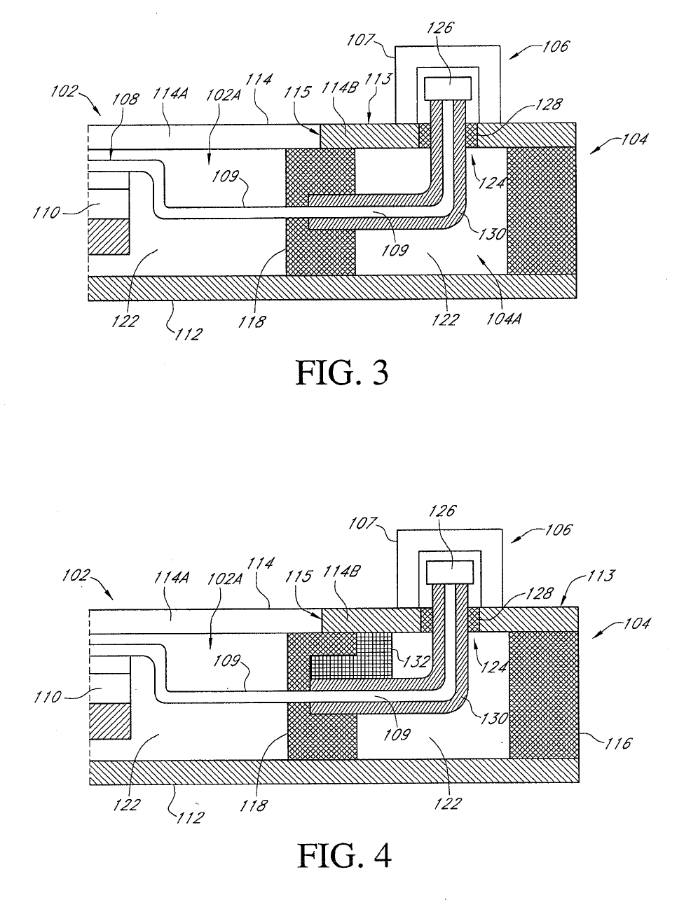

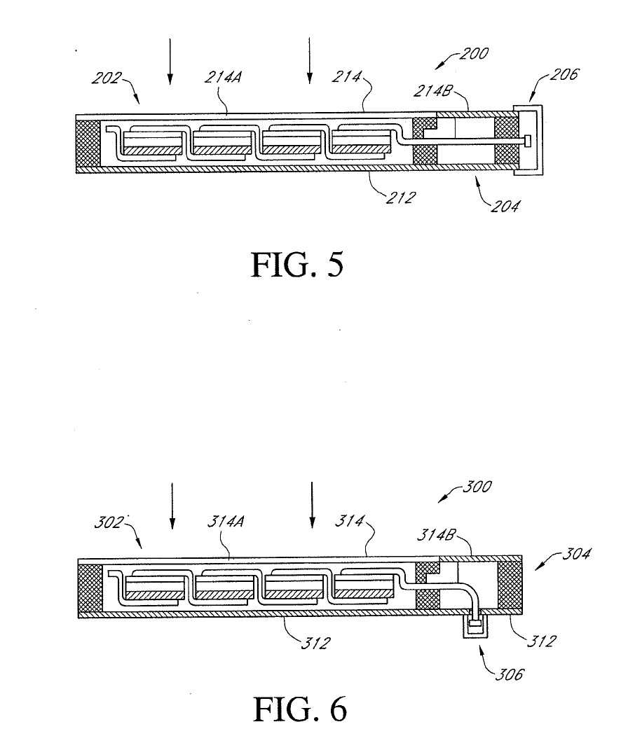

Reference will now be made to the drawings wherein like numerals refer to like parts throughout. FIG. 2A shows in plan view an embodiment of a flexible solar panel 100 of the present invention.

The flexible solar panel may comprise a module 102 having a module housing 102A, a flexible auxiliary unit 104 including an auxiliary unit housing 104A and a junction box 106 or connection housing attached to the auxiliary unit 104. A solar power generating solar cell circuit 108 is held in the module housing 102A. As will be explained more fully below, terminal leads 109 of a solar cell circuit 108 is extended from the module 102 to the junction box 106 through the auxiliary unit 104 in a well sealed manner while inhibiting any moisture seepage into the module housing. In this configuration, the auxiliary unit 104 forms a buffer zone between the module 102 and the junction box 106, which additionally seals the terminal leads 109 exiting the module 102 and entering junction box. Although in this embodiment the flexible solar panel 100 is exemplified with the module 102, the auxiliary unit 104 and the junction box 106, the flexible solar panel 100 of the present invention may have multiple modules with a single auxiliary unit or multiple auxiliary units as well as single or multiple junction boxes.

As shown in FIG. 2A in top view and in FIG. 2B in cross sectional side view, the flexible solar module has a flexible outer shell 100A that may be made of a bottom flexible protective sheet 112, a top flexible protective sheet 114, and a peripheral sealant wall 116 extending between the bottom and top flexible protective sheets and applied along the perimeter of them. An inner seal wall 118 divides the interior space of the shell into two, as the module housing and the auxiliary unit housing in which the components of the respective housings are placed. The peripheral sealant wall 116 may be made of a viscous moisture barrier sealant or a moisture barrier sealant tape. An examplary material for the peripheral sealant and the inner seal walls may be butyl rubber with desiccants having 5 to 13 mm width and 0.5 mm to 1.5 mm thickness.

The solar cell circuit 108 includes a number of solar cells 110 interconnected using a stringing technique that employs conductive leads 120, such as conductive wires or ribbons, to electrically connect the solar cells, preferably in series. However, the solar cell circuit 108 may also be formed using shingling techniques to interconnect the solar cells 110 without using conductive leads, such shingling principles are described above in the background section. Each solar cell 110 generally includes a substrate 110A, an absorber layer 110B formed over the substrate and a transparent layer 110C formed over the absorber layer 110B. The absorber layer 110B may be a Group IBIIIAVIA absorber layer such as a Cu(In, Ga) Seₑ compound layer. The substrate 110A may be a flexible foil substrate such as a stainless steel foil or an aluminum foil. There may be a back contact layer (not shown), such as a molybdenum layer between the substrate and the absorber layer. A current collecting structure (not shown) including a busbars and fingers is deposited onto a top surface of the transparent layer 110C, which is also the light receiving side of the solar cells. A support material 122 or encapsulant, such as ethylene vinyl acetate (EVA) and/or thermoplastic polyurethane (TPU), and thermoplastic polyolefins, fills the space surrounding the solar cell circuit 108 in the module housing. The support material 122 is a transparent material which fills any hollow space among the cells and tightly seals them into a module structure by covering their surfaces. The conductive leads 120 are connected to the solar cell strings using methods which are well known in the solar cell manufacturing technologies.

In this embodiment, the top flexible protective sheet 114 may comprise a first section 114A including a first material and a second section 114B including a second material. As shown in FIGS. 2A and 2B, the first section 114A of the top protective sheet forms the top of the module 102 and the second section 114B forms a top of the auxiliary unit 104. An intersection 115 separating the first and second sections 114A, 114B is placed adjacent a top of the inner seal 118 between the module housing 102A and the auxiliary unit housing 104A. The junction box 106, preferably a junction box enclosure 107, is preferably attached to a top surface 113 of the second section 114B of the top flexible protective sheet 114 covering the auxiliary unit housing 104A. The first material of the first section 114A may be different from the second material of the second section 114B, or at least the material of the top surface 113 of the second section of the top flexible protective sheet 114 of the flexible solar panel 100. The first and the second materials may be sheet materials including single or multiple material layers. As will be described more fully below, the second material of the second section 114B may be the same as the material of the bottom protective sheet 112 or another material having a top surface that is more compatible with the sealants or adhesives used to attach the junction box to the second section surface. The first section 114A and the second section 114B may be separate pieces that are brought together and sealed along the interface 115. Alternatively, the first and the second sections may be integrated and manufactured together as a single top flexible protective sheet. Of course, the second section may also include the material of the first section. In this particular case, an inner surface of the second section (the surface facing towards the auxiliary unit housing) may preferably be treated with a moisture sealant layer.

In modules employing thin film devices, such as thin film CIGS solar cells, it is important that the bottom protective sheets be a moisture barrier. The bottom flexible protective sheet 112 of the flexible solar panel 100 may typically be a polymeric sheet having moisture barrier characteristics such as TEDLAR®, a polyvinyl fluoride PVF film available from DuPont, Inc., or other polymeric sheet materials such as PVDF (Poly vinyledene difluoride), PET (poly ethylene teraphtalate), Perfluoro-alkyl vinyl ether, PA (polyamide) or PMMA (poly methyl methacrylate). The flexible bottom protective sheet 112 may be a non-transparent sheet and may preferably comprise a composite structure, i.e., multiple layers stacked and bonded, including one or more metallic layers such as aluminum layers between the polymeric sheets to further improve moisture resistance of the bottom flexible protective sheet. The metallic layer, or moisture barrier, may be interposed between polymeric sheets such as TEDLAR® layers or other polymeric material layers so that the polymeric sheet forms the outer surface exposed to the outside. For example, when an 18 to 50 um thick aluminum (Al) sheet is laminated into the structure of such TEDLAR sheets, very low water vapor transmission rates of 10⁻³ g/m²/day or lower can be achieved. In addition to its high moisture barrier property, TEDLAR exhibits good adhesion to the sealants used to adhere junction boxes or other module components to TEDLAR surfaces. TEDLAR forms moisture resistant seals with such a sealant used to attach junction boxes 107 to TEDLAR surfaces. An examplary flexible bottom protective sheet may include the structure of a top TEDLAR layer/Aluminum layer/PET layer/Primer and may have a thickness of about 0.4 mm. When the same material is used for the second section 114B of the top flexible protective sheet 114, the auxiliary unit 104 becomes more moisture resistant and moisture transmission through the path ways of terminal wires 109 is reduced.

Thus, the second section 114B of the top flexible protective sheet may be made of any polymeric sheet or polymeric-metal sheet combinations. The top surface 113 of the second section may be a polymeric back sheet material such as TEDLAR, PVDF, PET, perfluoro-alkyl vinyl ether, PA or PMMA. The junction box 106 on the solar module can be located on the second section 114B of the top flexible protective sheet 114 as shown in FIGS. 2A and 2B and attached to the polymeric materials on the top surface 113. It is easier to adhere the junction box to this material than the weatherable ETFE, FEP films that are mentioned in the background section. The flexible bottom protective sheet 112 as well as the second section 114B of the flexible top protective sheet 114 may at least include an outer polymeric layer, such as TEDLAR, covering a non-transparent inorganic moisture barrier layer such as a metallic layer, for example Al. The junction box enclosure 107 may be made of Noryl, PPE (poly phenylene ether), PET, Nylon, Polycarbonate, or PPE with PS (poly styrene) materials. Examplary adhesive that can be used to attach the junction box to the top surface 113 of the second section 114B may be silicone sealants such as Dow Corning PV804, Shinetsu KE220/CX220, Tonsan 15276 or adhesive tapes like 3M VHB 5952, Duplomont 9182. The adhesive tapes may need a primer to apply them to the surface materials.

Exemplary flexible and transparent materials for the first section 114A of the top flexible protective sheet may include ethylene tetrafluoroethylene (ETFE) under TEFZEL® commercial name or fluorinated ethylene propylene (FEP) from DuPont or poly vinylidene fluoride (PVDF) under KYNAR commercial name. The first section 114A may at least include an outer polymeric layer, such as ETFE, FEP or PVDF, covering a transparent inorganic moisture barrier layer such as Al₂O₃ or SiO₂. As explained above, although such materials are very weather-resistant materials, they have weaker adhesion to the junction box sealants (Silicone based one or two component systems, with room temperature cure chemistry) and adhesive tapes. The moisture transmission rate of an ETFE or FEP front sheet is around 1 to 10 g/m²/day. An examplary first section of the top protective sheet may include the structure of a top FEP, ETFE or PVDF layer/Adhesive film/Moisture barrier-Carrier film and may have a thickness in the range of 0.1 to 0.15 mm. As described in the background section, the carrier film may include PET poly(ethylene teraphthalate) and PEN poly(ethylene naphthalate). An examplary transparent moisture barrier material may include Al₂O₃ or SiO₂.

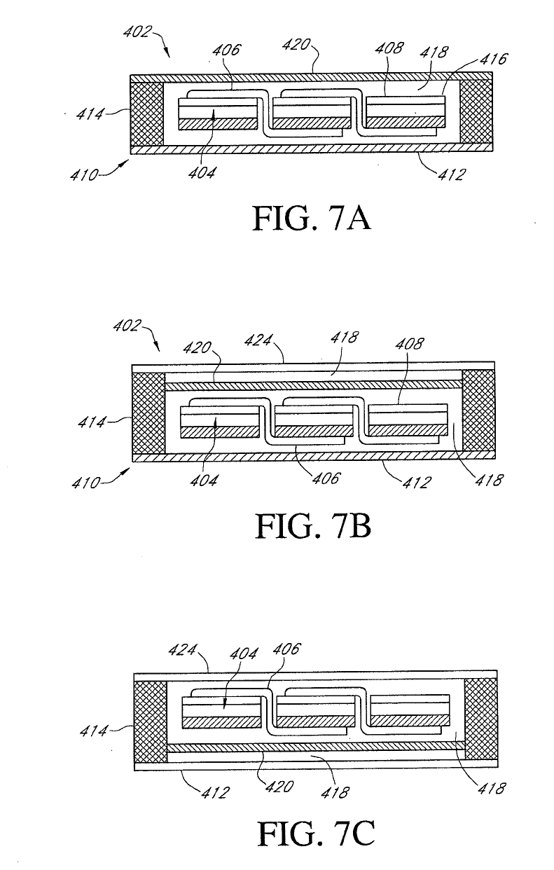

FIGS. 3 and 4 schematically illustrate various manners in which the auxiliary unit 104 and the junction box 106 of the flexible solar panel shown in FIGS. 2A and 2B are constructed.

In the embodiment shown in FIG. 3, the terminal wires 109 pass through the inner seal wall 118 and enter the auxiliary unit housing 104A, and then through openings 124 in the second section 114B of the top flexible protective sheet 114, connected to terminals 126 in the junction box 106. To reduce any moisture leakage in the auxiliary housing, a seal material 128 may be used to seal the holes 124. As described above, the junction box enclosure 107 is sealably attached to the top surface 113 of the second section 114B, which further encloses the openings 124. The portion of the terminal wires 109 extending from the inner seal wall 118 may be coated with a protective shield 130 made of a high dielectric strength and moisture resistant material. One end of the protective shield may be embedded into the inner seal wall 118, and the other end may extend into the junction box 106. The protective shield 130 may be formed and applied as a shrink tube and may be placed through the opening 128 in a tightly fitting manner to further minimize any moisture leakage inside the auxiliary housing 104A.

Examplary materials for the protective shield 130 may be the following materials: polyethylene terephthalate (PET), which is available under the commercial names Mylar, Melinex, heat shrink Mylar; polyimide (Kapton); polyolefins (EPS 300); and polyethylene napthalate (PEN).

As shown in FIG. 3 the intersection 115 between the first and second sections 114A, 114B may be located over the inner seal wall 118. However there may be other insulating and moisture resistant layers between the top of the inner seal wall 118 and the intersection 115 if the first and second sections are made of separate pieces.

As shown in FIG. 4, an insulating film 132, used with the inner seal wall 118, mechanically and electrically supports the second section 114B, when the top flexible protective sheet 114 is comprised of two different pieces and when only the edge of the first section 114A is placed on the inner seal wall 118. The insulating film 132 may include a high dielectric PET layer and adhesives on both sides to improve adhesion to the materials in contact. The dielectric constant of PET is equal or greater than 11 kV/mil and it preserves its electrical properties even with moisture penetration. There will be a potential difference between the live wires and the water that penetrates through the intersection 115 during a rainy season. This potential difference can be up to 1000 V DC. The material used as the insulating film 132 must be tested against partial discharge tests as not every material can withstand the 1000 V partial discharge tests without compromising its insulating electrical properties. EPE film from Madico Inc. of Woburn, Mass. is one of these materials that is available commercially. PET thickness may vary from 2 mil to 5 mil and adhesive thickness may be 2 to 4 mil on both sides. In this configuration, the insulating film 132 prevents any water leakage and electrical leakage through the intersection 115. The intersection 115 may open up and widen during installation or due to temperature cycling on the field, and the rubbery edge seal under the intersection 115 may break apart exposing the live wires to the water and moisture penetration. With the high dielectric strength insulating film 132 in place, there will be no electrical leakage from wires to the water and moisture penetrated through openings. The insulating film 132 also provides mechanical support for the junction box pocket as the intersection 115 is weak for any bending stress.

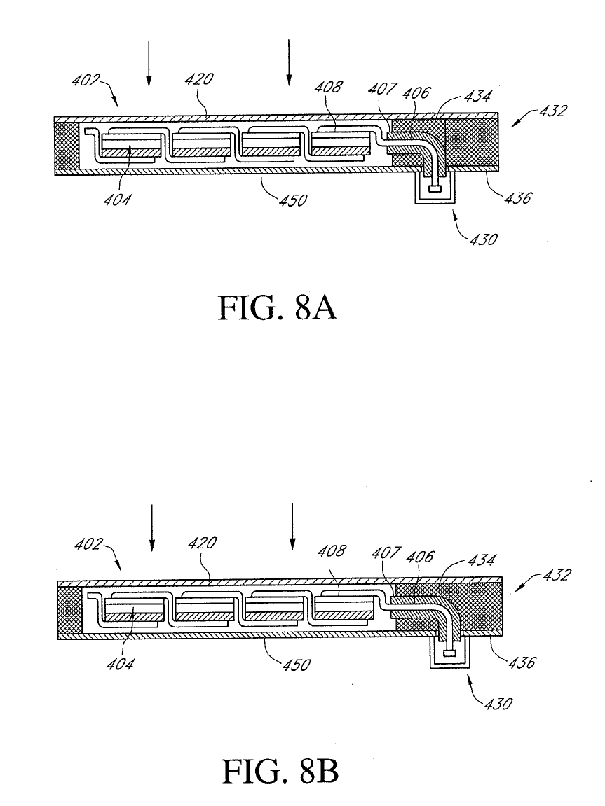

FIGS. 5 and 6 illustrate alternative locations for the junction box. As shown in FIG. 5, in a flexible solar panel 200 comprising a module 202, auxiliary unit 204 and a junction box 206, the junction box 206 may be attached to a side of the auxiliary unit. The solar panel 200 includes: a flexible top protective sheet 214 including a first section 214A which is transparent, and a second section 214B; and a flexible bottom protective sheet 212. In this embodiment, the junction box is attached to the outer surfaces of the flexible bottom protective sheet 212 and the second section 214B of the flexible top protective sheet that may include the same material, as described in the above embodiments. As shown in FIG. 6, in a flexible solar panel 300 comprising a module 302, auxiliary unit 304 and a junction box 306, the junction box 306 may be attached to the bottom of the auxiliary unit 304. The solar panel 300 includes: a flexible top protective sheet 314 including a first section 314A, which is transparent, and a second section 314B; and a flexible bottom protective sheet 312. In this embodiment, the junction box 306 is attached to the outer surface of the flexible bottom protective sheet 312.

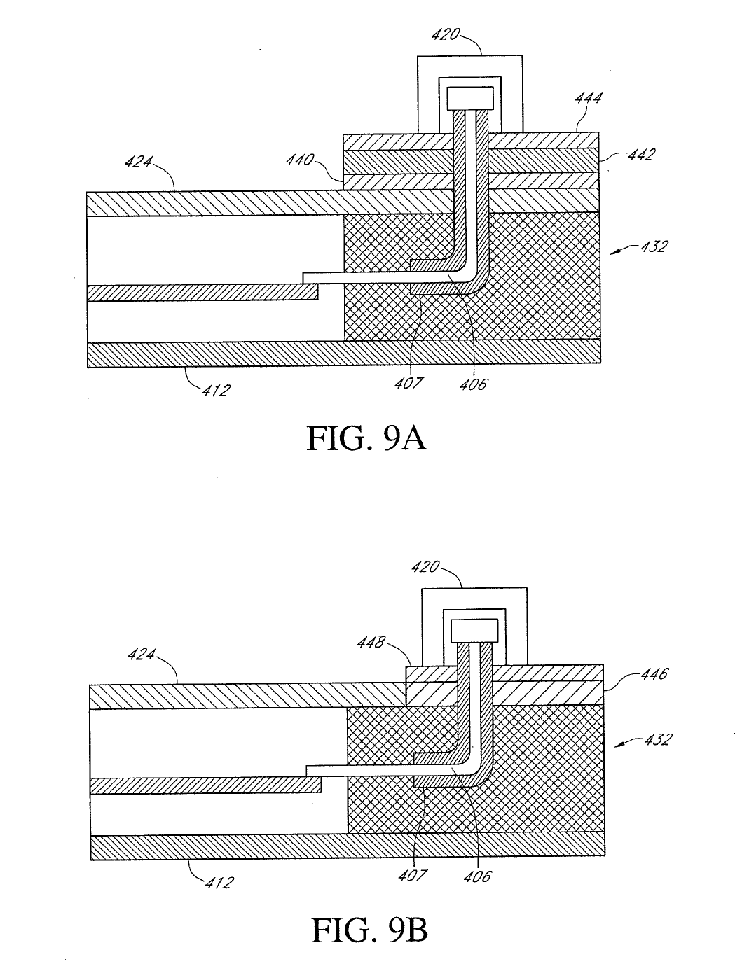

Turning now to FIGS. 7A-7C, several different embodiments of a solar cell module 402 is shown. In FIG. 7A, the module 402 includes a plurality of solar cells 404 that are coupled together, either by shingling or stringing, to form a solar power generating unit 408. In this particular implementation, the individual solar cells 404 are coupled together by conductors 406. The solar power generating unit 408 is contained within a housing 410 that affords some protection of the solar cells 404 from the exterior environment. In this implementation, the solar cells 404 are substantially the same as the solar cells 110 described above.

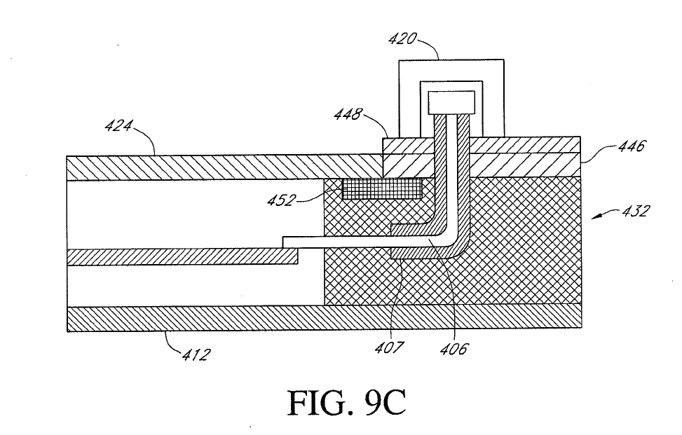

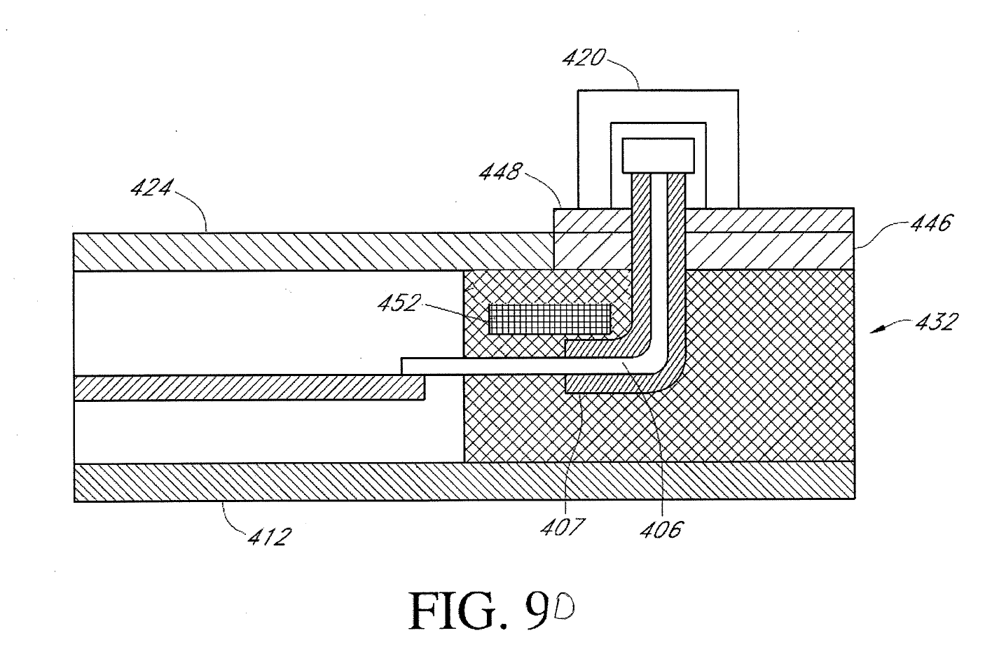

In this implementation, the housing 410 includes a bottom sheet 412 that is formed of a material that is preferably moisture resistant. The bottom sheet 412 can be formed in substantially the same manner as the bottom flexible protective sheets 112 described above and preferably includes an aluminum layer or some other metallic substrate or layer to inhibit moisture intrusion into the solar power generating unit 408. Sidewalls 414 of the housing are formed of a moisture barrier sealant tape 432 (FIGS. 8A-9C) or edge tape that has a composition similar to the composition of the peripheral sealant 116 and side walls 118 described above. The bottom sheet 412 and the side walls 414 define a space 416 into which the solar cells 404 are positioned. Typically, the solar cells 404 are positioned in the space 416 and the space is filled with an encapsulant 418 such as ethelyne vinyl acetate (EVA) or a polyolefin. In this implementation, the upper surface of the housing 410 is formed of a flexible glass sheet 420. The flexible glass sheet 420 is transparent to light so as to permit solar energy to be passed through to the solar cells 404 but is also a moisture barrier thereby providing additional protection to the solar cells 404 from moisture intrusion. In one implementation, the flexible glass sheet is thin between approximately 100 μm and 2 mm.

FIG. 7B illustrates another embodiment of a solar cell module 402 that uses a flexible glass sheet 420 as a moisture barrier. It will be understood that the flexible glass sheet 420 may be difficult to use in some applications as a front sheet due to its tendency to break. In the embodiment of FIG. 7B, the flexible glass sheet is positioned within the space 416 and is also surrounded by the encapsulant 418. The upper surface or front sheet of the housing 410 is formed using a flexible front sheet 424 that is transmissive to light. The flexible front sheet 424 is preferably formed, in one embodiment, of weatherable polymeric materials such as flourepolymer material like ETFE or PVDF, similar to the front sheet 114 described above. In this way, the flexible glass sheet 420 can be used as a moisture barrier and provide additional protection to the solar cells 404, however, the thin flexible glass sheet 420 is better resistant to damage as a result of being embedded in the encapsulant and positioned underneath the flexible front sheet 424 which provides a measure of protection against the glass sheet 420 being broken as a result of objects impacting on the housing 410. Both surfaces of the flexible glass sheet are supported by the encapsulant 418. In this implementation, the bottom sheet 412 and the sidewalls 414 are substantially the same as described above.

FIG. 7C illustrates yet another example of how a flexible glass sheet 420 can be used to provide additional moisture protection for the solar cells 404. In this implementation, the bottom sheet 412 does not include an aluminum layer and is formed of materials like hydrolysis and UV stable PET, PA, or a fluoropolymer like ETFE. The flexible glass sheet 420 is then either adhesively adhered to the inner side of the bottom sheet 412 via aa pressure sensitive adhesive, UV curable adhesive or is placed within an encapsulant material 418 in the manner previously described in FIG. 7B. The solar cells 404 can also be positioned within the encapuslant in the manner previously described and a flexible front sheet 424 can then be used to complete the housing 410.

The solar power generating units 408 of FIGS. 7A-7C are shown without a junction box connection similar to the connections shown in FIGS. 3-6. It will, however, be appreciated that a junction box connection to permit the current generated by the solar power generating units 408 will be needed. FIGS. 8A, 8B, and 9A to 9C illustrate examples of junction box connections that can be used with either the solar power units of FIGS. 7A-7C or the previously described solar power units of FIGS. 3-6.

Specifically referring to FIGS. 8A and 8B, an example of a junction box 430 positioned on the bottom side of the solar cell module 402. In each of the implementations of FIGS. 8A, 8B, and 9A to 9C, the routing of the conductor 406 from the solar power generating unit 408 to the junction box 430 occurs in a region of the edge tape 432 rather than in a separate auxiliary unit such as the auxiliary units 204 and 304 shown in FIGS. 5 and 6. As will be understood from the following description, eliminating the auxiliary unit and placing conductor 406 actually within the sidewall formed, in one embodiment by an edge tape 432, provides good protection against moisture intrusion into the solar power generating unit 408 and also results in greater efficiency in the use of the available space of the solar cell module 402.

In FIGS. 8A and 8B, the junction box 430 is formed so as to be positioned on the bottom side of the solar cell module 402. This implementation is advantageous in that if the flexible glass sheet 420 is used as a moisture intrusion component, either as the top surface as shown in FIG. 7A or intermediate to the top surface as shown in FIG. 7B, the junction box 430 may have to be positioned on the bottom side of the module 402 as it may be difficult to extend the conductors 406 through the flexible glass sheet 420 without breaking the flexible glass sheet 420. As is also shown, the conductors 406 are encapsulated by protective sheaths 407 which provide additional protection against moisture intrusion as described above.

In this particular implementation, the edge tape 432 includes a first narrow edge tape 434 that is positioned proximate the solar power generating unit 408 and a second edge tape 436 that provides additional moisture intrusion protection. The second edge tape 436 can be either the same width as the first edge tape 432 or wider [434 can be 7 to 12.7 mm wide and 0.5 mm to 1.4 mm thick, while 432 can be 7 to 30 mm wide and 0.5 to 1.4 mm thick] In the implementation of FIG. 8A, the conductors 406 and the protective sheath 407 are positioned so as to extend through the narrower edge tape 434 and an additional thin layer of edge tape can also be positioned on the narrower edge tape 434 above the conductor 406 and sheath 407 to provide additional insulation and protection. In the implementation of FIG. 8B, the conductor 406 extends through at the junction between the first edge tape 434 and the second edge tape 436. The junction box 430 can then be formed on the bottom surface or back sheet 450 of the module 402 which, as discussed above, may be formed of a material that is more amenable to receiving and securing the junction box 430.

In this implementation, the edge tape 432 is formed of a water intrusion resistant material such as desiccated butyl rubber or it may comprise other materials such as those described above in conjunction with the peripheral seals and 116 and sidewalls 118.

FIGS. 9A to 9C illustrate further embodiments of solar cell modules 402 which are formed so as to more efficiently use the available space. In this implementation, the auxiliary module has also been removed and the conductors 406 are coupled to the junction box 430 via the edge tape region 432 in a similar manner as described above in conjunction with FIGS. 8A and 8B.

With respect to FIG. 9A, the material comprising the top flexible protective sheet 424 extends across the top of the edge tape region or side seal region 432. In this implementation, the top protective sheet 424 may be comprised of the same material used to form the first section 114A of the top flexible protective sheet of FIG. 2 and may include ethylene tetrafluoroethylene (ETFE) under TEFZEL® commercial name or fluorinated ethylene propylene (FEP) from DuPont or poly vinylidene fluoride (PVDF) under the KYNAR commercial name. This sheet 424 may also include at least one outer polymeric layer, such as ETFE, FED or PVDF covering a transparent inorganic moisture barrier layer such as Al₂O₃ or SiO₂. In one exemplary embodiment, the top flexible protective sheet has a thickness of _{—}175 um

As adhesion and mechanical stress to these types of layers is complicated, a layer of junction box tape 440 such as VHB type junction box tape having a thickness of 1.1 mm may then be used to adhere a layer of material 442 that is substantially the same as the bottom protective sheet 412 and can comprise composite layers of metal and aluminum thereby providing a further moisture barrier. A sealant layer 444 is then positioned on top of the laminate protective sheet layer 442 and the junction box 420 is then positioned on the sealant layer 444. The sealant layer 444 may comprise a silicone layer or a junction box bonding tape layer having a thickness of 1.1 mm to attach the junction box onto the solar module and also inhibit moisture intrusion into the edge tape region 432.

FIG. 9B illustrates another example of how the conductors 406 can be routed through the edge tape or side seal region 432 and thereby eliminate the need for an auxiliary section. In this implementation, the top protective sheet 424 extends across only a portion of the edge tape or side seal region 432. The outer portion of the side seal region 432 is covered by a laminate layer 446 which, in one implementation, is comprised of the same material as the bottom protective layer 412 and has a thickness of 0.4 mm. The laminate layer 446 is adhered to the edge tape region 432 using either the common adhesive layer on 446, or a junction tape like 440 as in FIG. 9A, or the adhesive on the edge tape itself or the like. A sealant layer or tape 448, which can be a silicone sealant as described before, is then used to attach the junction box 430 to the side seal region 432.

Thus, it is possible to route the conductors 406 in the protective shell 407 through the tape that comprises the side seal region 432 and thereby reduce the overall footprint of the module 402. This allows for more modules 402 to be deployed into a solar panel per unit area thereby improving the efficiency of use of the area of the solar panel.

FIG. 9C illustrates additional embodiments of the edge tape region 432. As is shown in FIG. 9C, an insulating film 452 can also be positioned within the edge tape region 432 adjacent the laminate layer 446 to improve the adherence of the top flexible sheet 424 to the edge tape region 432 and provide mechanical support for the side seal region 432. As is shown in FIG. 9D, the insulating film 452 can also be recessed in the edge tape 432 to provide additional protection. The insulating film 452 can be comprised of materials similar to the materials of the insulating film 132, such as a high-dielectric PET layer like EPE available from Madico Inc. of Woburn, Mass. described above in conjunction with FIG. 4.

Although aspects and advantages of the present inventions are described herein with respect to certain preferred embodiments, modifications of the preferred embodiments will be apparent to those skilled in the art. The scope of the present invention should not be limited to the foregoing discussion but should be defined by the appended claims.

We claim:

1. A flexible solar power apparatus, comprising:
a first flexible bottom sheet and a second flexible top sheet;
a plurality of side sealing regions interposed between the first flexible bottom sheet and the second flexible top sheet so as to define at least one sealed module chamber having an interior space and exterior surfaces;
a solar cell circuit with interconnected solar cells having terminal wires positioned within the at least one sealed module chamber; and
a junction box formed on a first exterior surface of the at least one sealed module chamber, wherein terminal wires of the solar cell circuit are extended from the at least one sealed module chamber to the junction box through a first one of the plurality of side sealing regions so as to be surrounded by the material of the side sealing region from the interior space of the at least one sealed module chamber to be positioned adjacent the first exterior surface of the at least one sealed module chamber.

2. The apparatus of claim 1, wherein the at least one sealed module chamber includes a flexible bottom sheet of a first material and a first flexible top sheet of a second material that is transparent to visible light.

3. The apparatus of claim 2, wherein the first flexible top sheet includes a polymeric outer layer covering an inorganic transparent moisture barrier layer.

4. The apparatus of claim 3, wherein the polymeric outer layer includes one of ETFE (ethylene-tetrafluoroethylene), FEP (fluoro ethylene propylene) and PVDF (poly vinylidene fluoride).

5. The apparatus of claim 3, wherein the inorganic transparent moisture barrier layer includes one of aluminum oxide or silicon oxide.

6. The apparatus of claim 1, wherein the at least one sealed module chamber includes an encapsulant material coating the solar cells and filling the rest of the at least one sealed module chamber.

7. The apparatus of claim 1, wherein the terminal wires include a moisture resistant and insulating tubing that extends through the first side sealing region.

8. The apparatus of claim 2, wherein both the flexible bottom sheet and the second flexible top sheet include a polymeric outer layer covering an inorganic non-transparent moisture barrier layer TEDLAR® (polyvinyl fluoride).

9. The apparatus of claim 8, wherein the polymeric outer layer includes one of TEDLAR (polyvinyl fluoride), PVDF (Poly vinyledene difluoride), PET (poly ethylene teraphtalate), Perfluoro-alkyl vinyl ether, PA (polyamide) and PMMA (poly methyl methacrylate).

10. The apparatus of claim 8, wherein the inorganic non-transparent moisture barrier layer includes a metal film.

11. The apparatus of claim 1, wherein the solar cells include Group IBIIIAVIA thin film solar cells.

12. The apparatus of claim 2, wherein the first flexible top sheet comprises a sheet of flexible glass.

13. The apparatus of claim 2, further comprising a sheet of flexible glass that is interposed between the solar cells and the first flexible top sheet of the second material.

14. The apparatus of claim 2, wherein the flexible bottom sheet comprises a transparent layer and the apparatus further comprises a sheet of flexible glass that is interposed between the solar cells and the bottom sheet of the first material.

15. The apparatus of claim 1, wherein the junction box is positioned on an exterior surface of the at least one sealed module chamber adjacent the first flexible bottom sheet.

16. The apparatus of claim 1, wherein the junction box is positioned on an exterior surface of the at least one sealed module chamber adjacent the second flexible top sheet.

17. The apparatus of claim 1, wherein the first side sealing region is formed of an inner and an outer section of sealing tape and wherein the terminal wires are routed through the inner section of sealing tape.

18. The apparatus of claim 17, wherein the junction box is formed on an upper surface of the first side sealing region.

19. The apparatus of claim 18, wherein first flexible top sheet extends over all of the upper surface of the first side sealing region.

20. The apparatus of claim 19, further comprising a layer of junction box tape, a laminate protective layer and a sealant layer that are interposed between the first flexible top sheet and the junction box.

21. The apparatus of claim 18, wherein the first flexible top sheet extends over a first portion of the upper surface of the first side sealing region.

22. The apparatus of claim 21, further comprising a laminate layer that is positioned over the remaining portion of the upper surface of the first side sealing region not covered by the first flexible top sheet.

23. The apparatus of claim 22, further comprising a sealant layer that is positioned on the laminate layer and wherein the junction box is positioned on the sealant layer.

24. The apparatus of claim 22, further comprising an insulating film that is positioned underneath the interface between the laminate layer and the first flexible top sheet.

25. The apparatus of claim 24, wherein the insulating film is recessed within the side sealing region underneath the interface between the laminate layer and the first flexible top sheet.

26. A flexible solar panel, comprising:
a bottom protective sheet of a first material;
a front protective sheet formed of a second material spaced from the bottom protective sheet, so as to define a space therebetween;
an edge moisture sealant wall formed between the bottom protective sheet and the front protective sheet along the perimeters of the bottom and the front protective sheet, thereby sealing the perimeters of the bottom protective sheet and the front protective sheet against moisture so as to define a sealed module chamber;
a solar cell circuit having terminal wires including a plurality of interconnected solar cells is disposed in the sealed module chamber;
a moisture protection layer that is positioned in the sealed module chamber so as to inhibit moisture intrusion toward the solar cells from the direction of the front protective sheet; and
a junction box mounted on the flexible solar panel that is connected to the terminal wires of the solar cell circuit.

27. The apparatus of claim 26, wherein the front protective sheet comprises a sheet of flexible glass that also defines the moisture protection layer.

28. The apparatus of claim 26, wherein the moisture protection layer comprises a layer of flexible glass that is positioned within the sealed module chamber so as to be interposed between the front protective sheet and the solar cell circuit.

29. The apparatus of claim 26, wherein the front protective sheet is transparent to visible light and the bottom protective sheet is more moisture resistant than the front protective sheet.

30. The apparatus of claim 26, wherein the at least one sealed module chamber includes an encapsulant material coating the solar cells and filling the rest of the sealed module chamber.

31. The apparatus of claim 26, wherein the terminal wires include a moisture resistant and insulating tubing.

32. The apparatus of claim 26, wherein the solar cells include Group IBIIIAVIA thin film solar cells.

33. The apparatus of claim 26, wherein the edge moisture sealant wall comprises a solid region of moisture resistant material and wherein the terminal wires extend through the edge moisture sealant wall to the junction box so that the terminal wires are surrounded by the material of the edge moisture sealant wall substantially from the interior of the sealed moisture chamber to an exterior surface upon which the junction box is mounted.

34. The apparatus of claim 33, wherein the edge moisture sealant wall is formed of an inner and an outer section of sealing tape and wherein the terminal wires are routed through the inner section of sealing tape.

35. The apparatus of claim 26, wherein the junction box is positioned on an exterior surface of the sealed module chamber adjacent the bottom protective sheet.

36. The apparatus of claim 26, wherein the junction box is positioned on an exterior surface of a first side sealing region of the sealed module chamber adjacent the front protective sheet.

37. The apparatus of claim 36, wherein the junction box is formed on an upper surface of the first side sealing region.

38. The apparatus of claim 37, wherein first flexible top sheet extends over all of the upper surface of the first side sealing region.

39. The apparatus of claim 38, further comprising a layer of junction box tape, a laminate protective layer and a sealant layer that are interposed between the first flexible top sheet and the junction box.

40. The apparatus of claim 37, wherein the first flexible top sheet extends over a first portion of the upper surface of the first side sealing region.

41. The apparatus of claim 40, further comprising a laminate layer that is positioned over the remaining portion of the upper surface of the first side sealing region not covered by the first flexible top sheet.

42. The apparatus of claim 41, further comprising an insulating film that is positioned underneath the interface between the laminate layer and the first flexible top sheet.

43. The apparatus of claim 41, wherein the insulating film is recessed within the side sealing region underneath the interface between the laminate layer and the first flexible top sheet.
